(19) United States
(12) Patent Application Publication
(10) Pub. No.: US 2026/0313781 A1
(43) Pub. Date: Oct. 8, 2026

(54) HEAT DISSIPATION DEVICE

(71) Applicant: ASUSTeK COMPUTER INC., Taipei City (TW)

(72) Inventors: Po-Ting Chen, Taipei City (TW); Chang-Hung Chen, Taipei City (TW); Yu-Nian Lai, Taipei City (TW); Szu-Chieh Wang, Taipei City (TW); Jung-Li Kuo, Taipei City (TW); Chih-Chung Lin, Taipei City (TW); Ming-Han Hou, Taipei City (TW)

(73) Assignee: ASUSTeK COMPUTER INC., Taipei City (TW)

(21) Appl. No.: 19/290,330

(22) Filed: Aug. 4, 2025

(30) Foreign Application Priority Data
Apr. 8, 2025 (TW) 114203435

(51) Int. Cl. H05K 1/02; H01R 12/51; H01R 13/04

(52) U.S. Cl. CPC H05K 1/0203; H01R 12/51; H01R 13/04; H05K 1/0213

(57) ABSTRACT

A heat dissipation device provided is adapted to be installed on a circuit board. The circuit board includes a heat generation element. The heat dissipation device includes a heat dissipation module and multiple second electrical contacts. The heat dissipation module is adapted to correspond to the heat generation element and be fixed on the circuit board. The heat dissipation module has multiple first electrical contacts. The second electrical contacts are adjacent to the heat generation element and disposed on the circuit board. When the heat dissipation device is installed on the circuit board, the first electrical contacts directly contact the second electrical contacts.

### CROSS-REFERENCE TO RELATED APPLICATION

This application claims the priority benefit of Taiwan application serial no. 114203435, filed on Apr. 8, 2025. The entirety of the above-mentioned patent application is hereby incorporated by reference herein and made a part of this specification.

### BACKGROUND

### Technical Field

The disclosure relates to a heat dissipation device.

### Related Art

Currently, a general heat dissipation device is disposed in the chassis of a computer and uses multiple transmission lines to be electrically connected to multiple different devices. For example, a water-cooling heat dissipation device includes a pump, a water-cooling device, and multiple fans. The devices need to use multiple transmission lines to be respectively connected through the water-cooling device installed on a motherboard. However, this arrangement needs to confirm whether each transmission line is connected to a correct device during assembly to avoid incorrect connections and cause the heat dissipation device to malfunction, resulting in inconvenience for assembly. In addition, the multiple transmission lines may also make an overall appearance to look messy, which is not aesthetically pleasing when subsequently paired with a transparent casing or a heat dissipation device having lighting effects.

### SUMMARY

The disclosure provides a heat dissipation device, which does not need multiple transmission lines to be electrically connected to multiple elements.

The heat dissipation device of the disclosure is adapted to be installed on a circuit board. The circuit board has a heat generation element. The heat dissipation device includes a heat dissipation module and multiple second electrical contacts. The heat dissipation module is adapted to correspond to the heat generation element and be fixed on the circuit board. The heat dissipation module has multiple first electrical contacts. The second electrical contacts are adjacent to the heat generation element and disposed on the circuit board. When the heat dissipation device is installed on the circuit board, the first electrical contacts directly contact the second electrical contacts respectively.

Based on the above, according to the heat dissipation device of the disclosure, since the first electrical contacts and the second electrical contacts correspond to each other and directly contact, when the heat dissipation device is installed on the circuit board, the heat dissipation module may be directly electrically connected to the circuit board through the first electrical contacts and the second electrical contacts, and then respectively connected to different devices through the circuit board without the need to use multiple transmission lines to be respectively connected to different devices, which is quite convenient for assembly.

In order to make the features and advantages of the disclosure more comprehensible, the following examples are given and described in detail with the accompanying drawings as follows.

### BRIEF DESCRIPTION OF THE DRAWINGS

FIG. 1A is a schematic view of a heat dissipation device according to the disclosure.

FIG. 1B is an exploded view of FIG. 1A.

FIG. 2 is an exploded view of another embodiment of FIG. 1A.

FIG. 3 is a schematic view of a heat dissipation device according to another embodiment of the disclosure.

FIG. 4 is a schematic view of a heat dissipation device according to another embodiment of the disclosure.

FIG. 5A is a schematic view of a heat dissipation device according to another embodiment of the disclosure.

FIG. 5B is an exploded view of FIG. 5A.

FIG. 6 is a schematic view of a heat dissipation device according to another embodiment of the disclosure.

### DESCRIPTION OF THE EMBODIMENTS

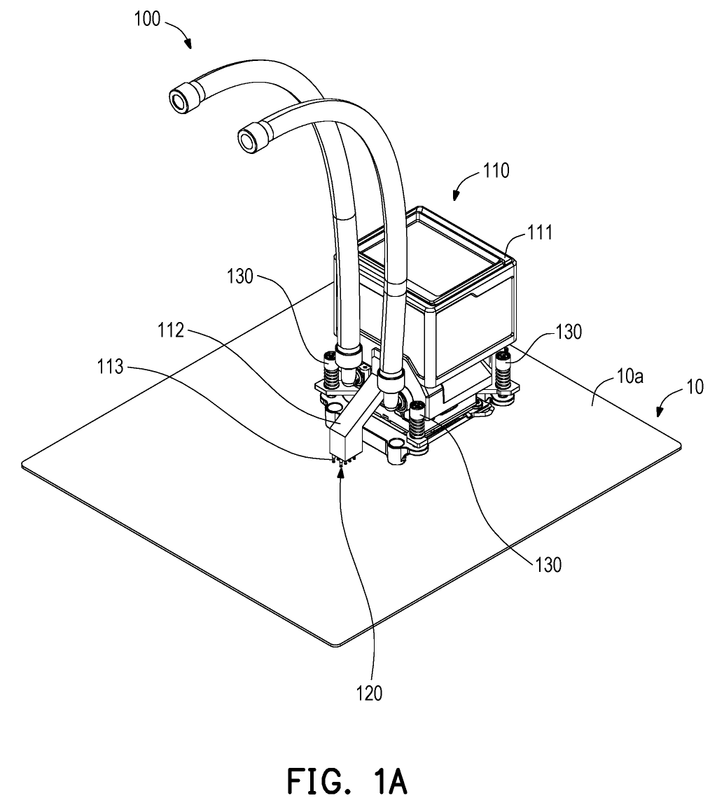

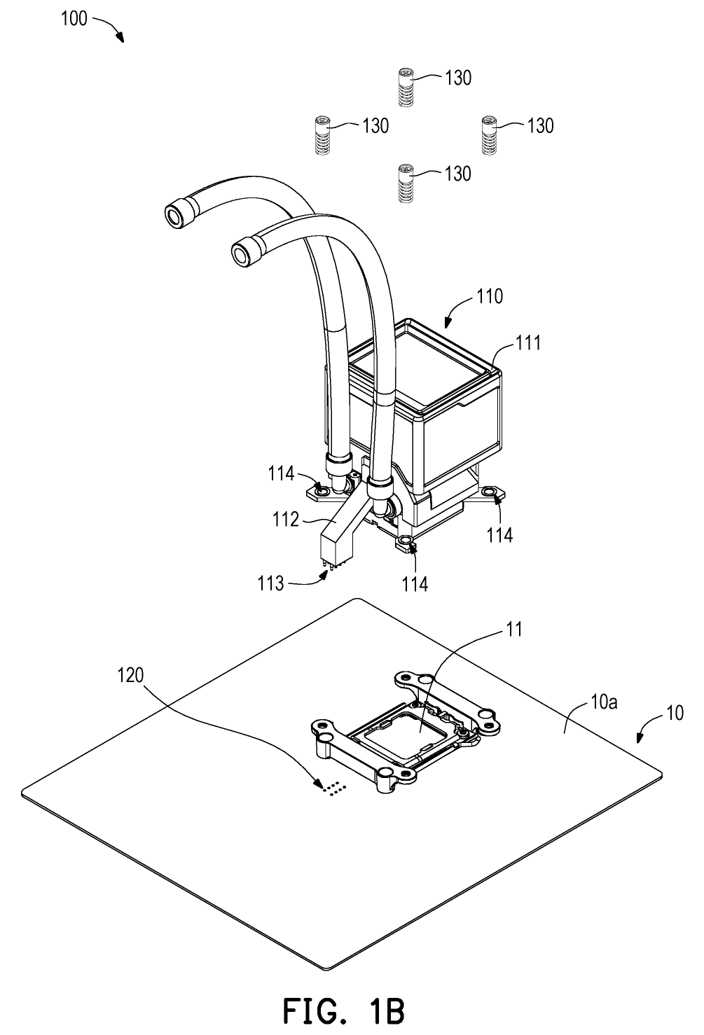

Please refer to FIG. 1A and FIG. 1B. A heat dissipation device 100 of the disclosure is adapted to be installed on a circuit board 10. The circuit board 10 has a heat generation element 11. The heat dissipation device 100 includes a heat dissipation module 110 and multiple second electrical contacts 120. The heat dissipation module 110 is adapted to correspond to the heat generation element 11 and be fixed on the circuit board 10. The heat dissipation module 110 has multiple first electrical contacts 113. The second electrical contacts 120 are adjacent to the heat generation element 11 and disposed on the circuit board 10. When the heat dissipation device 100 is installed on the circuit board 10, the first electrical contacts 113 directly contact the second electrical contacts 120, thereby allowing the heat dissipation module 110 to be electrically connected to the circuit board 10.

Following the above, in the embodiment, the circuit board 10 has a surface 10a. The second electrical contacts 120 are disposed on the surface 10a. The heat dissipation module 110 further includes a body 111 and a connector 112. The body 111 is adapted to correspond to the heat generation element 11 and be fixed on the circuit board 10. The first electrical contacts 113 are disposed on the connector 112. The connector 112 is disposed on one side of the body 111 and fixed on the body 111. In addition, the first electrical contacts 113 are, for example, multiple pogo pins. In other embodiments, the first electrical contacts 113 may also be multiple elastic pieces or other forms of contacts, as long as the first electrical contacts 113 may directly contact and be electrically connected to the second electrical contacts 120. However, the disclosure is not limited thereto. On the other hand, the heat dissipation device 100 further includes multiple locking members 130. The heat dissipation module 110 further includes multiple fixing holes 114. The locking members 130 allow the heat dissipation module 110 to be fixed on the circuit board 10 through the fixing holes 114.

Please continue to refer to FIG. 1B. The second electrical contacts 120 are disposed on the circuit board 10 and correspond to the first electrical contacts 113, so that when the heat dissipation module 110 is fixed on the circuit board 10, the first electrical contacts 113 may directly contact the second electrical contacts 120. When a quantity of the connector 112 is two or more than two, and are disposed on multiple sides of the heat dissipation module 110, the second electrical contacts 120 are disposed on the surface 10a of the circuit board 10 and distributed at a position corresponding to the first electrical contacts 113. That is to say, the second electrical contacts 120 may be correspondingly disposed on the surface 10a of the circuit board 10 based on a position where the first electrical contacts 113 are disposed, so that when the heat dissipation module 110 is installed on the circuit board 10, the first electrical contacts 113 may directly contact the second electrical contacts 120. In the embodiment, the first electrical contacts 113 are disposed on the connector 112. In other embodiments, the first electrical contacts 113 may also be directly disposed on the body 111 of the heat dissipation module 110. When the heat dissipation module 110 is installed on the circuit board 10, and the second electrical contacts 120 are disposed at a position where the heat dissipation module 110 contacts the circuit board 10, the first electrical contacts 113 are allowed to directly contact the second electrical contacts 120. On the other hand, in the embodiment, the heat generation element 11 is, for example, a chip.

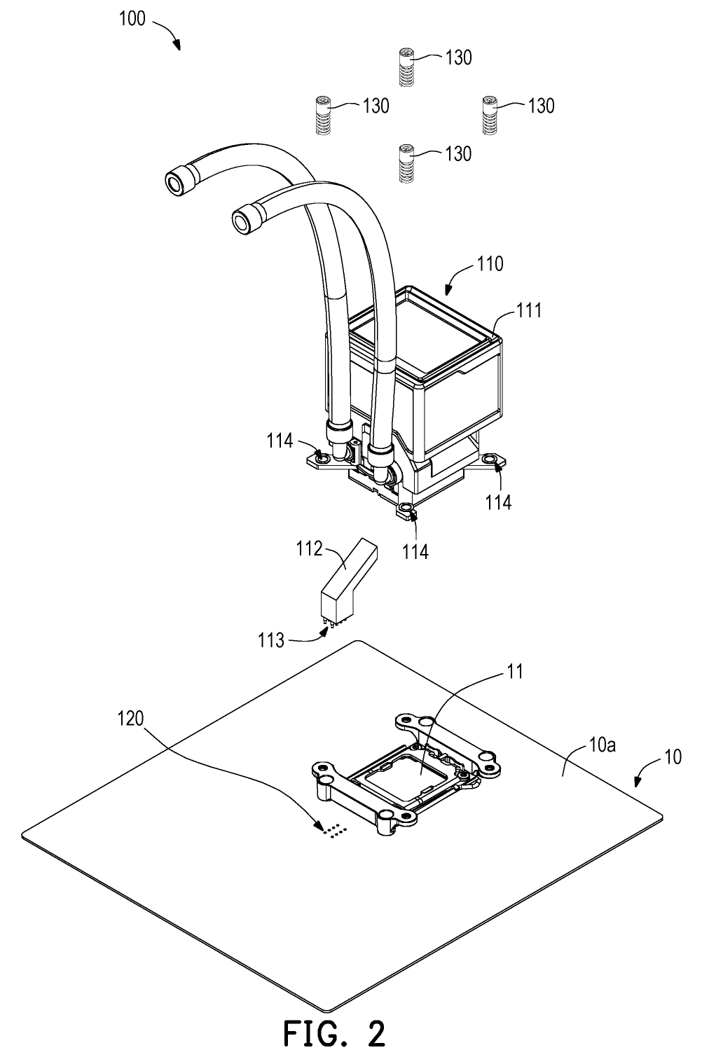

Please refer to FIG. 2. In the embodiment, the connector 112 is detachably disposed on the body 111. In detail, the connector 112 is disposed on one side of the body 111 and may be detached from the body 111. When the heat dissipation module 110 is to be installed on the circuit board 10, the connector 112 is first installed on the body 111, and then the heat dissipation module 110 is fixed on the circuit board 10. In addition, the heat dissipation module 110 may also be first fixed on the circuit board 10, and then the connector 112 is installed at a corresponding position that corresponds to a position of the second electrical contacts 120, allowing the first electrical contacts 113 on the connector 112 to directly contact the second electrical contacts 120. That is to say, in the embodiment, a position where the connector 112 is disposed on the body 111 may be adjusted based on the position where the second electrical contacts 120 are disposed on the circuit board 10, allowing the heat dissipation device 100 to be more convenient for installation.

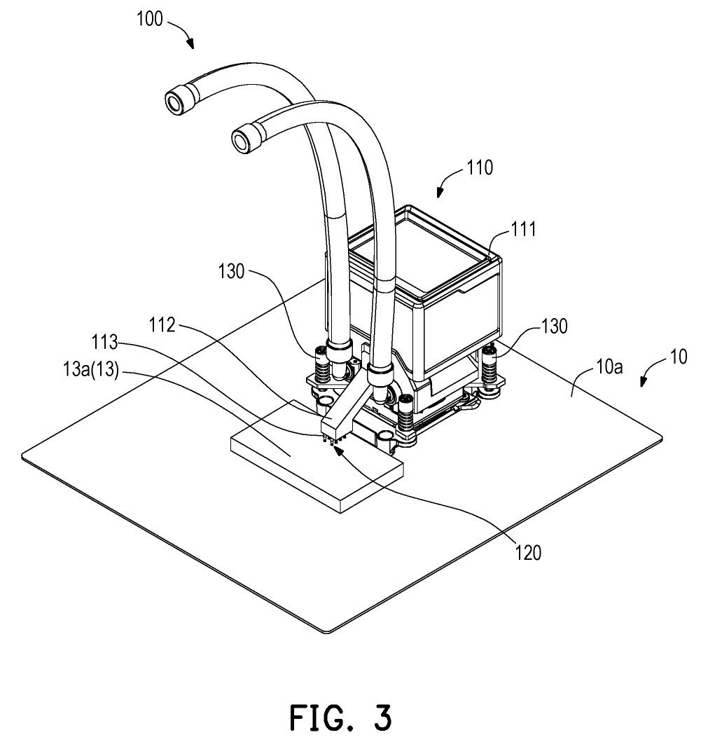

Please refer to FIG. 3. Another embodiment illustrated therein is substantially the same as the embodiment of FIG. 1A. The difference between the two is that the circuit board 10 further has at least one peripheral structure 13. The second electrical contacts 120 are disposed on the at least one peripheral structure 13. In detail, the peripheral structure 13 may be a heat dissipation sheet 13a. The second electrical contacts 120 are disposed on the heat dissipation sheet 13a. The first electrical contacts 113 are disposed on the connector 112. The connector 112 is disposed on a same side of the heat dissipation module 110 relative to the second electrical contacts 120 corresponding to the second electrical contacts 120. When the heat dissipation module 110 is installed on the circuit board 10, the first electrical contacts 113 are directly connected to the second electrical contacts 120, allowing the heat dissipation module 110 to be electrically connected to the circuit board 10.

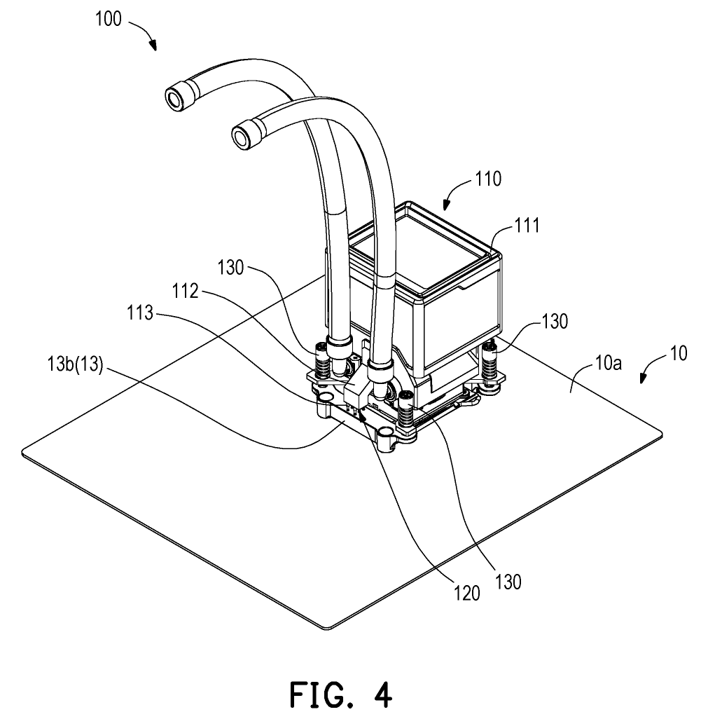

Please refer to FIG. 4. Another embodiment illustrated therein is substantially the same as the embodiment of FIG. 3. The difference between the two is that the peripheral structure 13 may be a fastener 13b. The fastener 13b is disposed on the circuit board 10 and configured to fix the heat dissipation module 110. The second electrical contacts 120 are disposed on the fastener 13b. In addition, in the embodiment, the first electrical contacts 113 are disposed on the connector 112 and correspond to the second electrical contacts 120. When the heat dissipation module 110 is installed on the circuit board 10, the first electrical contacts 113 are directly connected to the second electrical contacts 120, allowing the heat dissipation module 110 to be electrically connected to the circuit board 10. In addition, the second electrical contacts 120 may also be dispersedly disposed on the surface 10aof the circuit board 10 and the peripheral structure 13. The first electrical contacts 113 are dispersedly disposed on the body 111 or the connector 112 corresponding to the second electrical contacts 120, as long as the first electrical contacts 113 may be allowed to be directly connected to the second electrical contacts 120. However, the disclosure is not limited thereto. On the other hand, in the embodiment, the peripheral structure 13 is the fastener 13b. In other embodiments, the peripheral structure 13 may also be other device disposed on the circuit board 10, as long as the first electrical contact 113 may be allowed to be electrically connected to the second electrical contacts 120 disposed on the device. However, the disclosure is not limited thereto.

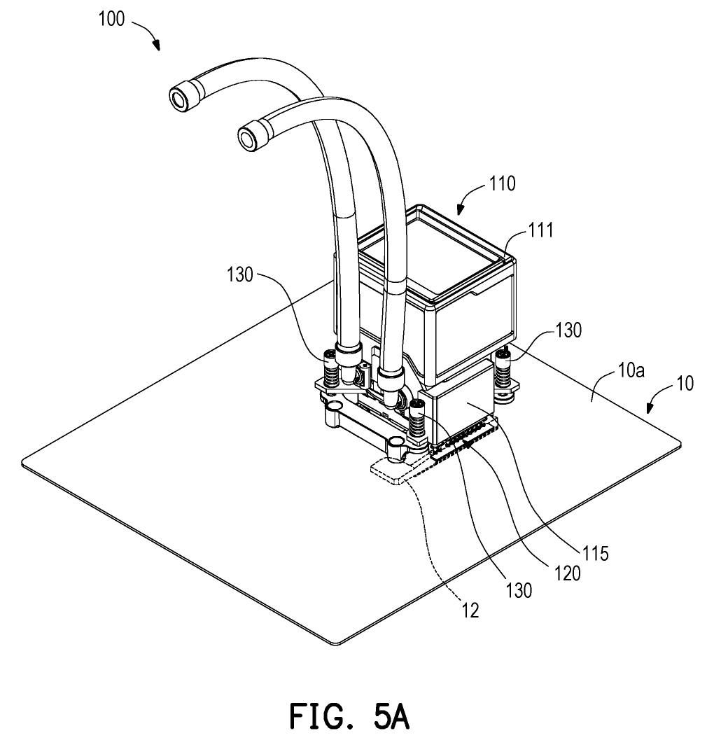

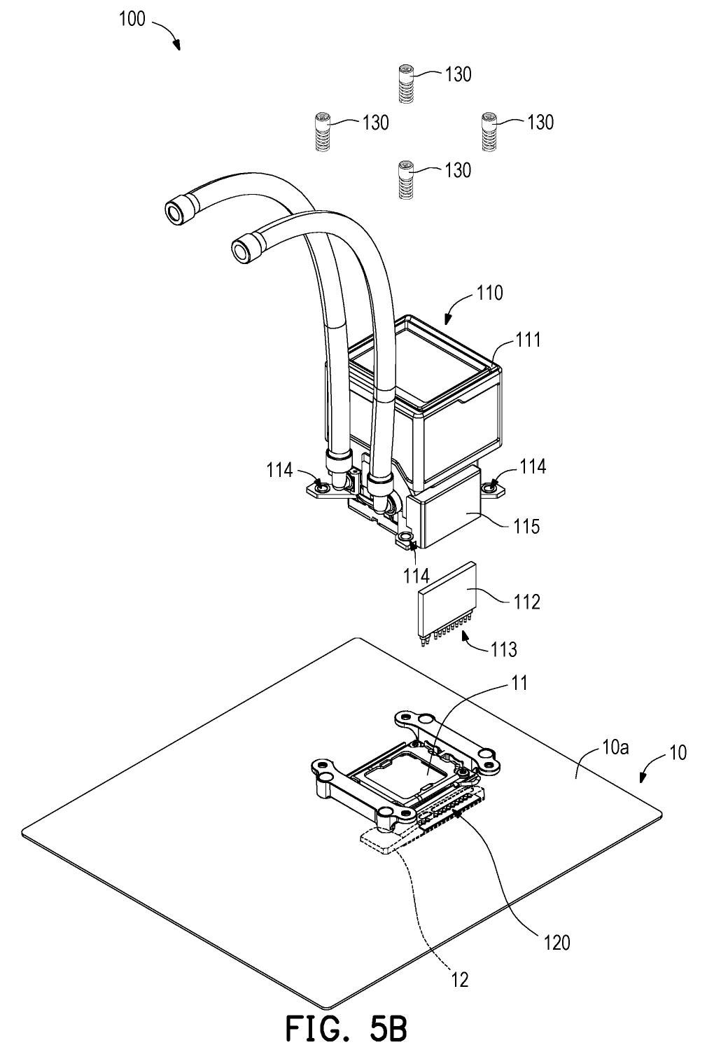

Please refer to FIG. 5A and FIG. 5B. Another embodiment illustrated therein is substantially the same as the embodiment of FIG. 1A. The difference between the two is that the heat dissipation device 100 further includes a connection port 115. The connection port 115 is fixed to one side of the body 111. The connector 112 is detachably disposed within the connection port 115. In addition, in the embodiment, the second electrical contacts 120 are disposed within a connection device 12 to protect the second electrical contacts 120. The connection device 12 is disposed at a position corresponding to the first electrical contacts 113, and disposed on the surface 10a of the circuit board 10. In detail, in the embodiment, when the heat dissipation module 110 is to be installed on the circuit board 10, the connector 112 is first disposed within the connection port 115, so that the first electrical contacts 113 on the connector 112 may be directly connected to the second electrical contacts 120 on the circuit board 10. In the embodiment, since the connector 112 is detachable, a user may select a corresponding connector 112 according to the second electrical contacts 120 on different circuit boards 10, allowing more convenience for installation.

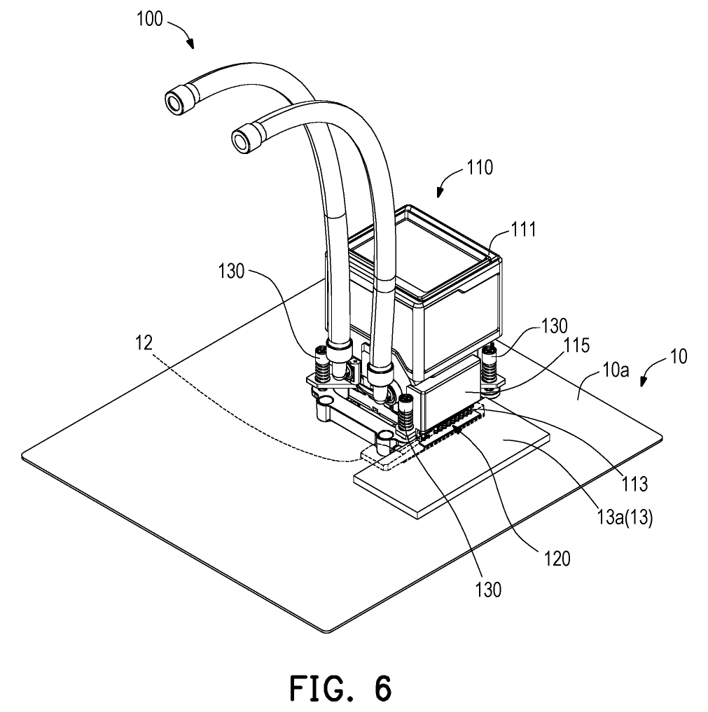

Please refer to FIG. 6. Another embodiment illustrated therein is substantially the same as the embodiment of FIG. 5A. The difference between the two is that the connection device 12 is disposed on the heat dissipation sheet 13a. The connector 112 is disposed on the heat dissipation module 110 and corresponds to one side of the connection device 12. In addition, in other embodiments, the connector 112 may also be directly disposed on the body 111. Alternatively, the first electrical contacts 113 may be directly disposed on the body 111, and correspond to the connection device 12, so that the first electrical contacts 113 may directly contact the second electrical contacts 120. However, the disclosure is not limited thereto. In the embodiment, the connection device 12 is disposed on the heat dissipation sheet 13a. In other embodiments, the connection device 12 may also be disposed on other devices, as long as the first electrical contacts 113 may be allowed to be directly connected to the second electrical contacts 120. However, the disclosure is not limited thereto.

In summary, according to the heat dissipation device of the disclosure, since the first electrical contacts and the second electrical contacts correspond to each other and directly contact, when the heat dissipation device is installed on the circuit board, the heat dissipation module may be directly electrically connected to the circuit board through the first electrical contacts and the second electrical contacts, and then respectively connected to different devices through the circuit board without the need to use multiple transmission lines to be respectively connected to different devices, which is quite convenient for assembly.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A heat dissipation device, adapted to be installed on a circuit board, the circuit board having a heat generation element, and the heat dissipation device comprising:
a heat dissipation module, adapted to correspond to the heat generation element and be fixed on the circuit board, and having a plurality of first electrical contacts; and
a plurality of second electrical contacts, adjacent to the heat generation element and disposed on the circuit board;
wherein when the heat dissipation device is installed on the circuit board, the first electrical contacts directly contact the second electrical contacts respectively.

2. The heat dissipation device according to claim 1, wherein the heat dissipation module further comprises:
a body, adapted to correspond to the heat generation element and be fixed on the circuit board; and
a connector, disposed on one side of the body, and the first electrical contacts being disposed on the connector.

3. The heat dissipation device according to claim 2, wherein the connector is fixed to the body.

4. The heat dissipation device according to claim 2, wherein the connector is detachably disposed on the body.

5. The heat dissipation device according to claim 1, wherein the heat dissipation module further comprises:
a body, adapted to correspond to the heat generation element and be fixed on the circuit board;
a connection port, fixed to one side of the body; and
a connector, detachably connected to the connection port, and the first electrical contacts being disposed on the connector.

6. The heat dissipation device according to claim 1, wherein the circuit board further has at least one peripheral structure, and the second electrical contacts are disposed on the at least one peripheral structure.

7. The heat dissipation device according to claim 6, wherein the second electrical contacts are dispersedly disposed on the circuit board and the at least one peripheral structure.

8. The heat dissipation device according to claim 1, wherein the first electrical contacts are disposed on a same side of the heat dissipation module.

9. The heat dissipation device according to claim 8, wherein the second electrical contacts correspond to the first electrical contacts and are disposed on a same side of the circuit board.

10. The heat dissipation device according to claim 1, wherein the first electrical contacts are dispersedly disposed on the heat dissipation module.

11. The heat dissipation device according to claim 10, wherein the second electrical contacts correspond to the first electrical contacts and are dispersedly disposed on the circuit board.

12. The heat dissipation device according to claim 1, further comprising a plurality of locking members, wherein the locking members are adapted to fix the heat dissipation module on the circuit board through a plurality of fixing holes of the heat dissipation module.

13. The heat dissipation device according to claim 1, wherein at least a portion of the second electrical contacts is disposed within at least one connection device.

14. The heat dissipation device according to claim 13, wherein the circuit board further has at least one peripheral structure, and the connection device is disposed on the at least one peripheral structure.
